(19) United States
(12) Patent Application Publication
(10) Pub. No.: US 2024/0191351 A1
(43) Pub. Date: Jun. 13, 2024

(54) SUBSTRATE PROCESSING SYSTEM

(71) Applicant: ASM IP Holding B.V., Almere (NL)

(72) Inventor: Dieter Pierreux, Pepingen (BE)

(21) Appl. No.: 18/530,444

(22) Filed: Dec. 6, 2023

Related U.S. Application Data
(60) Provisional application No. 63/386,438, filed on Dec. 7, 2022.

(51) Int. Cl. C23C 16/44; C23C 16/30; C23C 16/34; C23C 16/455; C23C 16/52; H01L 21/02

(52) U.S. Cl. CPC C23C 16/4412; C23C 16/308; C23C 16/345; C23C 16/45527; C23C 16/45544; C23C 16/52; H01L 21/0214; H01L 21/0217; H01L 21/0228

(57) ABSTRACT

A substrate processing system and a method for forming a layer on one or more substrates is disclosed. Embodiments, of the recently described substrate processing system comprise a process chamber, a precursor storage module, a pump, a pump valve and a controller configured to control the provision of the precursor flow to the process chamber.

### CROSS-REFERENCE TO RELATED APPLICATION(S)

This application claims the benefit of U.S. Provisional Application 63/386,438 filed on Dec. 7, 2022, the entire contents of which are incorporated herein by reference.

### FIELD OF INVENTION

The present disclosure relates to semiconductor processing. More specifically, it relates to a substrate processing system for forming a layer on one or more substrates and a method of forming the layer.

### BACKGROUND OF THE DISCLOSURE

Formation of layers on substrates by a deposition process may be considered one of the important processing steps in the semiconductor industry. This may be due to the fact that the properties of the layers are typically influenced by the process parameters.

The deposition processes typically require the use of precursor gases to form the layers. These precursor gases may be obtained from a liquid source or a solid source.

The advances in semiconductor industry may require, on one hand, decreasing the cost per wafer processing, while on the other hand, increase the chip density per wafer. Decreasing the cost per wafer may be achieved by implementing the use of batch process apparatuses in the fab that can process a plurality of wafers one at a time. Increasing chip density may be achieved by the use of larger diameter wafers. These may however, lead to an increased consumption of precursors gases, as a consequence, to deposit layers on the substrates. This may then result in increased cost per wafer due to the increased consumption of the precursors.

Therefore, there may be a need to optimize precursor usage in semiconductor processing.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter

It may be an object of the present disclosure to provide a substrate processing system for optimizing precursor usage.

In a first aspect, the present disclosure relates to a substrate processing system. The substrate processing system may be suitable for forming a layer on one or more substrates. The substrate processing system may comprise a process chamber. The process chamber may be constructed and arranged to receive one or more substrates. The system may also comprise a precursor storage module that may be constructed and arranged to provide a precursor flow to the process chamber. The system may also comprise a pump for removing an exhaust gas from the process chamber. The pump may be operably connected to the process chamber via a pump valve. The system may also comprise a controller that may be operably connected to the precursor storage module and to the pump valve. The controller may be configured to execute instructions stored in a non-transitory computer readable medium to control a process for forming the layer. The process may comprise closing the pump valve prior to providing a precursor flow to the process chamber, providing the precursor flow while the pump valve may be kept closed, stopping the precursor flow, to the process chamber, and opening the pump valve after stopping the precursor flow. The controller may be programmed to repeat the process and to lower the precursor flow during each repetition.

The substrate processing system according to embodiments of the first aspect of the present disclosure may allow for an optimized precursor usage. Optimized precursor usage may advantageously lead to reducing precursor waste.

It may be an advantage of embodiments of the first aspect that the cost for processing may be reduced thanks to the reduced precursor waste.

It may be an advantage of embodiments of the first aspect that process sustainability may be improved thanks to the optimized precursor usage and reduced precursor waste.

It may be an advantage of embodiments of the first aspect that it may provide for monitoring precursor concentration in the exhaust gas, thereby allowing optimized control on precursor usage.

It may be an advantage of embodiments of the first aspect that the lifetime of the pump may be prolonged since duty cycle of the pump may be reduced.

It may be an advantage of embodiments of the first aspect that maintenance interruptions regarding the pump may be reduced thanks to the prolonged pump lifetime.

It may be an advantage of embodiments of the first aspect that maintenance interruptions regarding maintenance of the process chamber may be reduced thanks to the optimized precursor usage.

It may be an advantage of embodiments of the first aspect that processing of substrates comprising high surface enhancement structures may be done in an economical way.

It may be an advantage of embodiments of the first aspect that the processing of, particularly. 3DDRAM and 3DNAND memory devices may be made economical thanks to reduced precursor waste as these devices may require increased amount of precursor usage due to the presence of high surface enhancement structures on the one or more substrates.

It may further be an advantage of embodiments of the first aspect that it aids in processing of substrates with improved thickness uniformity.

In a second aspect, the present disclosure relates to a method of forming a layer on one or more substrates. The method may comprise providing, in a process chamber, one or more substrates. The one or more substrates may have a surface suitable for forming a layer. The process chamber may be operably connected to a pump via a pump valve. The method may further comprise processing the one or more substrates in the process chamber. The processing may comprise providing, to the process chamber, a precursor flow while the pump valve may be kept closed. The processing may further comprise stopping the precursor flow, to the process chamber, and opening the pump valve after stopping the precursor flow, thereby, removing an exhaust gas from the process chamber by the pump. The method may further comprise repeating the processing, whereby the precursor flow may be lowered during each repetition.

The method according to embodiments of the second aspect of the present disclosure may allow for an optimized precursor usage, thereby reducing precursor waste.

It may be an advantage of embodiments of the second aspect that processing of substrates comprising high surface enhancement structures may be done in an economical way thanks to the optimized precursor usage. This may particularly be advantageous when forming layers using Atomic Layer Deposition (ALD) since presence of high surface enhancement structures may require high precursor doses for obtaining full saturation.

It may be an advantage of embodiments of the second aspect that processing of semiconductor devices may be manufactured in a more economical way thanks to reduced precursor waste.

It may further be an advantage of embodiments of the second aspect that thickness uniformity of the layer formed on the substrate may be improved. This may further provide the advantage of improved reliability for further processes in the semiconductor manufacturing that the substrates having such layers with improved thickness uniformity are subjected to.

In a third aspect, the present disclosure relates to a method of forming a layer on one or more substrates. The method may comprise providing, in a process chamber, one or more substrates having a surface. The surface may comprise a surface enhancement structure. The surface enhancement structure may have a surface area greater than 14 m² on each of the one or more substrates. The method may further comprise processing the one or more substrates, thereby forming the layer on the surface. The processing may comprise providing a precursor flow to a process chamber. A pump valve that may be positioned in between the process chamber and a pump for removing an exhaust gas from the process chamber, may be kept closed during the processing

The method according to embodiments of the third aspect of the preset disclosure may allow for soaking the one or substrates by the precursor flow. This may improve surface coverage of the substrate by the precursor that may be comprised in the precursor flow, thereby allowing advantageously to improve precursor usage.

It may be an advantage of embodiments of the third aspect of the preset disclosure that surface coverage of the substrate may be improved incrementally, whereby precursor waste may thus, be decreased incrementally.

It may further be an advantage of embodiments of the third aspect of the preset disclosure that processing of 3D memory structures, such as, for example, 3D NAND OR 3D DDRAM, may be manufactured in a more economical way as the processing of these devices may require higher amount of precursor usage due to the presence of 3D structures on the surface of the substrate.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

Like reference numbers will be used for like elements in the drawings unless stated otherwise. Reference signs in the claims shall not be understood as limiting the scope.

FIG. 1: represents schematically a substrate processing system according to embodiments of the first aspect of the present disclosure.

FIG. 2: represents schematically a substrate processing system according to an embodiment of the first aspect of the present disclosure.

FIG. 3: represents schematically a substrate processing system according to an embodiment of the first aspect of the present disclosure.

FIG. 4: represents schematically a method according to embodiments of the second aspect of the present disclosure.

FIGS. 5a and 5b: FIG. 5a shows a graph of loading test measurement representing growth per cycle (GPC) as a function of line position for after provision of NH₃ precursor flow and FIG. 5b represents schematically the mode of measurement.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub-combinations of the various processes, systems, and configurations, and other features, functions, acts, and/or properties disclosed herein, as well as any and all equivalents thereof.

It is to be noticed that the term “comprising”, as used herein, should not be interpreted as being restricted to the means listed thereafter. It does not exclude other elements or steps. It is thus, to be interpreted as specifying the presence of the stated features, steps or components as referred to. However, it does not prevent one or more other steps, components, or features, or groups thereof from being present or being added.

It is to be noticed that the term “comprise substantially” used in the claims refers that further components than those specifically mentioned can, but not necessarily have to, be present, namely those not materially affecting the essential characteristics of the material, compound, or composition referred to.

Reference throughout the specification to “embodiments” or “one embodiment” or “an embodiment” means that a particular structure, feature step described in connection with the embodiment is included in at least one embodiment of the present disclosure. Thus, phrases appearing such as “in an embodiment” or “in one embodiment” in different places throughout the specification are not necessarily all referring to the same embodiment, but may. Furthermore, the particular features, structures or characteristics maybe combined in any suitable manner, as would be apparent to one of the ordinary skill in the art from the disclosure, in one or more embodiments.

Reference throughout the specification to “some embodiments” means that a particular structure, feature, step described in connection with these embodiments is included in some of the embodiments of the present invention. Thus, phrases appearing such as “in some embodiments” in different places throughout the specification are not necessarily referring to the same collection of embodiments but may.

Furthermore, the terms first, second, third, and the like in the description and in the claims, are used for distinguishing between similar elements and not necessarily for describing a sequence, either temporally, spatially, in ranking, or in any other manner. It is to be understood that the terms so used are interchangeable under appropriate circumstances and that the embodiments of the disclosure described herein are capable of operation in other sequences than described or illustrated herein.

The following terms are provided only to help in the understanding of the disclosure.

As used herein and unless provided otherwise, the term “surface enhancement structures” may refer to structures designed to be present on a substrate to purposefully increase the topography.

As used herein and unless provided otherwise, the term “surface enhancement” may refer to a ratio of the surface area of a device wafer (i.e. a substrate with device structures present thereon) to the surface area of a blanket wafer (i.e. a substrate having no device structures thereon).

As used herein and unless provided otherwise, the term “full saturation” may refer to a level during growth of a film, particularly when performing an ALD process, on a substrate surface, where the growth per cycle (GPC) is not increased anymore upon further precursor exposure.

As used herein and unless provided otherwise, the term “loading effect” may refer to an effect, whereby for a certain set of process parameters the performance degrades upon adding extra process wafers (i.e. substrates) having high surface enhancement structures inside the process chamber. This may require adaptation of the process parameters.

As used herein and unless provided otherwise, the term “pre-determined precursor dose” may refer to the dose of the precursor, particularly when performing an ALD process, that may be based on the number of device wafers in a process chamber, on the knowledge of the area of the surface enhancement.

As used herein and unless provided otherwise, the term “pre-determined percentage of saturation” may refer to the saturation level over the wafer surface, on which film deposition occurs, particularly when performing an ALD process.

As used herein and unless provided otherwise, the term “compensating the feedback signal” may refer to adjusting the pre-determined precursor dose to be sent to the process chamber.

As used herein and unless provided otherwise, the term “time lag” may refer to a period of time between stopping the precursor flow to the process chamber and opening the pump valve. This time lag may also be referred to as “soak time” or “soak” or “soak period”.

As used herein and unless provided otherwise, the term “process substrate” may refer to a substrate that may already have received any sort of semiconductor processing. It may also comprise semi-processed semiconductor device structures on its surface

As used herein and unless provided otherwise, the term “trench” may refer to a gap defined by an opening having a rectangular shape or a square shape. The gap may have a bottom surface opposite to the opening that may be defined by the substrate, by a layer present on the substrate or by a structure present on the substrate. The bottom surface may be bound by lateral sidewalls, thereby forming the rectangular or the square shape. The sidewalls may comprise a semiconductor material, a dielectric material, a metal or combinations thereof.

As used herein and unless provided otherwise, the term “slit” may refer to a trench having a bottom surface, where the bottom surface may be bounded only by two opposing sidewalls.

As used herein and unless provided otherwise, the term “lateral trench” may refer to a gap extending longitudinally along an axis being parallel to the surface of the substrate.

As used herein and unless provided otherwise, the term “intermediate 3D memory structure” may refer to a 3D memory device structure, whose manufacturing has not been completed yet.

The disclosure will now be described by a detailed description of several embodiments of the disclosure. It is clear that other embodiments of the disclosure can be configured according to the knowledge of persons skilled in the art in the absence of departure from the technical teaching of the disclosure. The disclosure is limited only by the terms of the claims included herein.

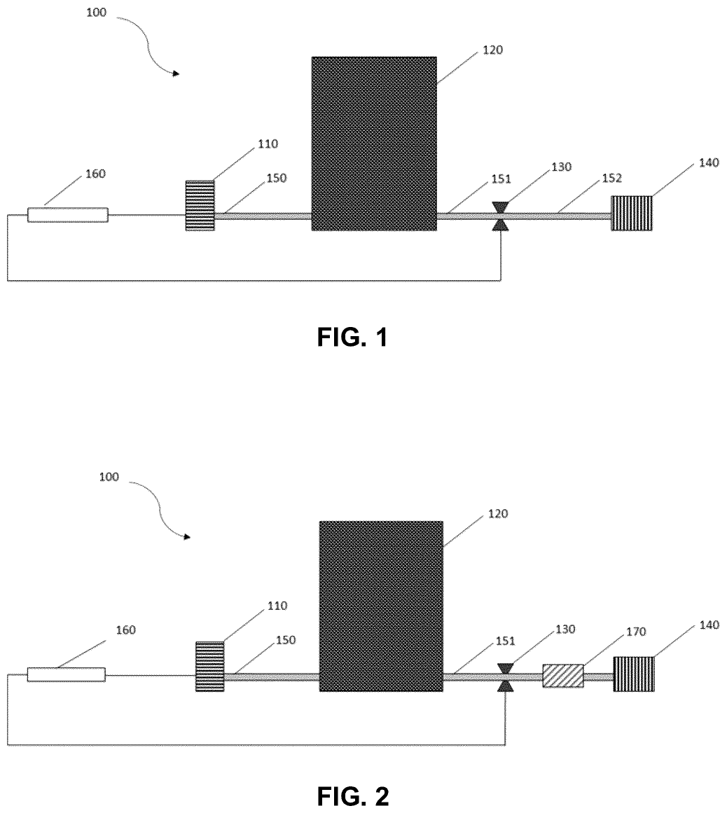

FIG. 1 represents schematically a substrate processing system (100) according to embodiments of the first aspect of the present disclosure.

Described herein is a substrate processing system (100). The substrate processing system (100) may be suitable for forming a layer on one or more substrates. The substrate processing system (100) may comprise a process chamber (120). The process chamber (120) may be constructed and arranged to receive one or more substrates.

In some embodiments, the process chamber may thus, be comprised in a single substrate processing apparatus.

In some embodiments, the process chamber may thus, be comprised in a batch apparatus. Batch apparatus may refer to the fact that a plurality of substrates may be processed in the process chamber comprised in such an apparatus.

In some embodiments, the batch apparatus may be an apparatus extending in a longitudinal direction. In some embodiments, the longitudinal direction may be a vertical direction with respect to the ground that the apparatus is positioned. Thus, in some embodiments, the batch apparatus may be a vertical batch apparatus. The vertical batch apparatus may, in embodiments, be a vertical furnace and the process chamber may thus, be comprised in the vertical furnace, whereby the process chamber may also extend in the longitudinal direction being vertical.

In some embodiments, the longitudinal direction may be a horizontal direction with respect to the ground that the apparatus is positioned. Thus, in some embodiments, the batch apparatus may be a horizontal batch apparatus and the process chamber may thus, extend in the longitudinal direction being horizontal.

The substrate processing system (100) may also comprise a precursor storage module (110). The precursor storage module (110) may be constructed and arranged to provide, to the process chamber (120), a precursor flow. The precursor flow may be provided to the process chamber (120) through a conduit (150) positioned between the precursor storage module (110) and the process chamber (120). The precursor conduit (150) may comprise valves and flow controllers to control and adjust the flow of the precursor.

In some embodiments, the precursor flow may have a pre-determined precursor dose. This may be advantageous when the process chamber is comprised in an apparatus suitable for ALD.

In embodiments, the precursor flow may comprise a precursor gas. The precursor gas may allow for forming a layer on the one or more substrates. The precursor gas may be obtained from a liquid precursor source or a solid precursor source. Thus, the precursor storage module may comprise a vessel constructed and arranged to store the liquid precursor source or the solid precursor source.

The precursor gas may be provided in the presence of a carrier gas in the precursor flow. The carrier gas may comprise N₂, and noble gases such as for example, Ar, Ne, He, Xe and Kr.

In some embodiments, the carrier gas may comprise substantially N₂, Ar, He. or combinations thereof.

In some embodiments, the provision of the precursor flow may comprise providing a first precursor flow and a second precursor flow. The second precursor flow may be different from the first precursor flow. This may provide the advantage of forming a layer of a binary compound on the one or more substrates. The first precursor flow may comprise a first precursor gas and the second precursor flow may comprise a second precursor gas, where the second precursor gas may be different than the first precursor gas. This layer may be such as, for example, a layer of silicon nitride comprising a first precursor flow comprising di-chlorosilane (DCS), and a second precursor flow comprising ammonia (NH₃) or when forming a layer of doped silicon comprising a first precursor flow comprising silane (SiH₄) and a second precursor flow comprising a dopant precursor such as for example phosphine.

In some embodiments, the first precursor flow and the second precursor flow may be provided alternatingly to the process chamber (120) for forming the binary compound. The formation of the binary compound with the alternating provision of the precursor flows may be carried out in an ALD apparatus.

In some embodiments, the first precursor flow and the second precursor flow may be provided during an overlapping period to the process chamber (120) for forming the binary compound.

In some embodiments, the first precursor flow and the second precursor flow may be co-flown to the process chamber. In other words, the first precursor flow and the second precursor flow may be provided to the process chamber at the same time during a 100% overlapping period. The formation of the binary compound with co-flowing of the precursor flows may be carried out in a CVD apparatus. The formation of the binary compound with co-flowing of the precursor flows may also be carried out in an ALD apparatus.

In some embodiments, the provision of the precursor flow may comprise providing a first precursor flow, a second precursor flow and a third precursor flow. The first, the second and the third precursor flow may be different from one another. This may provide the advantage of forming a layer of a ternary compound on the one or more substrates. The first precursor flow may comprise a first precursor gas, the second precursor flow may comprise a second precursor gas, and the third precursor flow may comprise a third precursor gas, where the first, the second and the third precursor gas may be different from one another. This layer may be such as, for example, a layer of silicon oxy nitride comprising provision of a first precursor flow comprising di-chlorosilane (DCS), a second precursor flow comprising ammonia (NH₃) and a third precursor flow comprising nitrous oxide (N₂O). This layer may also be such as, for example, hafnium aluminum oxide (HfAl_{X}O_{Y}) comprising provision of a first precursor flow comprising Tetrakis (ethylmethylamino) hafnium (TEMAHf), a second precursor flow comprising trimethylaluminum (TMA) and a third precursor flow comprising ozone (O₃).

In particular, in the methods and systems according to the present disclosure the precursor is a solid precursor comprising a metal or a metalloid. More particularly, said metal is selected from an alkaline metal, an alkaline earth metal, a transition metal, a rare earth metal or a combination thereof. More particularly, said metalloid, an element that has properties that are intermediate between those of metals and nonmetals, is silicon, boron, germanium, arsenic, antimony and/or tellurium. The solid precursor may also comprise one or more ligands, the one or more ligands being selected from H, halogens, alkyls, alkenyls, alkynes, carbonyls, dienyls, beta-diketonates, substituted or unsubstituted cyclodienyls, substituted or unsubstituted aryls or a combination thereof. Suitable halogens include F, Br, Cl, and/or I. Suitable alkyls, alkenyls, alkynes, dienyls, and cyclodienyls are typically C1 to C8 compounds. Suitable substituents on the cyclodienyls and aryls include C1 to C3 alkyls. Suitable beta-diketonates include 1,1,1,5,5,5-hexafluoropentane-2,4-dionate (hfac) and/or 2,4-pentanedione (hacac). In particular embodiments the solid precursor is a homoleptic chemical compound (a metal compound where all ligands are identical) or a heteroleptic chemical compound (a metal compound having two or more different types of ligand). In further particular embodiments the solid precursor comprises a metal-carbon bond. In further particular embodiments the solid precursor comprises a pi complex. An exemplary solid precursor is HfCl₄.

In the calculation of the consumption of solid precursor other factors such as the inlet gases in the solid precursor vessel (e.g. carrier gas and the gas determining the pressure of the precursor) are taken into account in addition to the flow rate in the process line. To account therefore typically a conversion factor, defined by the user, could be used.

In particular, in the methods and systems according to the present disclosure the precursor is a liquid precursor comprising a metal, more particularly, said metal is selected from an alkaline metal, an alkaline earth metal, a transition metal, a rare earth metal or a combination thereof. The liquid precursor may also comprise one or more ligands, the one or more ligands being selected from H, halogens, alkyls, alkenyls, alkynes, carbonyls, dienyls, beta-diketonates, substituted or unsubstituted cyclodienyls, substituted or unsubstituted aryls or a combination thereof. Suitable halogens include F, Br, Cl, and/or I. In particular embodiments the liquid precursor is a homoleptic chemical compound (a metal compound where all ligands are identical) or a heteroleptic chemical compound (a metal compound having two or more different types of ligand). In further particular embodiments the liquid precursor comprises a metal-carbon bond. In further particular embodiments the liquid precursor comprises a pi complex.

Exemplary precursors are Trimethylaluminum (TMA), tetrakis-ethylmethylaminohafnium (TEMAHf), octa chlorotrisilane (OCTS), N,N,N′,N′-tetraethylsilanediamine, Trichlorosilane, Dichlorosilane, Tetraethylorthosilicate (TEOS), Trimethylborate (TMB), Trichloroethane, Boron tribrornide, Phosphorous oxychloride, Fluorotriethoxysilane (FTES), Tetrakis-dimethylamino Titanium (TDMAT), Tetrakis-diethylamino (TDEAT), CuTMVS. Trimethylcyclotetrasiloxane (TOMCATS), Diethylsilane, Triethylborate (TEB), Trimethyl Phosphite (TMPI), TitaniumChloride TiCl₄, Trisilane Si₃H₈ and Triethylphosphate (TEPO), Molybdenum pentachloride MoCl₅, Molybdenumdioxi dichloride MoO₂Cl₂.

In some embodiments, the first precursor flow, the second precursor flow and the third precursor flow may be provided alternatingly to the process chamber (120) for forming the ternary compound. The formation of the ternary compound with the alternating provision of the precursor flows may be carried out in an ALD apparatus.

In some embodiments, the first precursor flow, the second precursor flow and the third precursor flow may be provided during an overlapping period to the process chamber (120) for forming the ternary compound.

In some embodiments, the first precursor flow, the second precursor flow and the third precursor flow may be co-flown to the process chamber. In other words, the first precursor flow and the second precursor flow may be provided to the process chamber at the same time during a 100% overlapping period. The formation of the ternary compound with co-flowing of the precursor flows may be carried out in a CVD apparatus. The formation of the binary compound with co-flowing of the precursor flows may also be carried out in an ALD apparatus.

In some embodiments, the provision of the precursor flow may comprise providing a first precursor flow, a second precursor flow, a third precursor flow and a fourth precursor flow. The first, the second, the third and the fourth precursor flow may be different from one another. This may provide the advantage of forming a layer of a quaternary compound on the one or more substrates. The first precursor flow may comprise a first precursor gas, the second precursor flow may comprise a second precursor gas, the third precursor flow may comprise a third precursor gas, and the fourth precursor flow may comprise a fourth precursor gas where the first, the second, the third and the fourth precursor gas may be different from one another. This layer may be such as, for example, a layer of indium gallium zinc oxide (IGZO).

In some embodiments, the first precursor flow, the second precursor flow, the third and the fourth precursor flow may be provided alternatingly to the process chamber (120) for forming the quaternary compound. The formation of the quaternary compound with the alternating provision of the precursor flows may be carried out in an ALD apparatus.

In some embodiments, the first precursor flow, the second precursor flow, the third precursor flow and the fourth precursor flow may be co-flown to the process chamber. In other words, the first precursor flow, the second precursor flow, the third precursor flow and the fourth precursor flow may be provided to the process chamber at the same time during a 100% overlapping period. The formation of the binary compound with co-flowing of the precursor flows may be carried out in a CVD apparatus.

The substrate processing system (100) may further comprise a pump (140). The pump may be suitable for removing an exhaust gas from the process chamber (120). The pump (140) may be operably connected to the process chamber (120) via a pump valve (130). The exhaust gas may comprise an unreacted portion of the precursor gas comprised in the precursor flow. The substrate processing system (100) may further comprise a controller (160). The controller (160) may be operably connected to the precursor storage module (110) and to the pump valve (130). The controller (160) may be configured to execute instructions that may be stored in a non-transitory computer readable medium to control a process for forming the layer.

In some embodiments, the controller may be configured to include a processor for executing instructions stored in the non-transitory computer readable medium.

The process may comprise closing the pump valve (130) prior to providing the precursor flow to the process chamber (120). The process may further comprise providing the precursor flow to the process chamber (120) while the pump valve (130) may be kept closed. In a substrate processing system, where ALD process is to take place, this may allow for obtaining a desired percentage of saturation of the surface of the one or more substrates with the precursor gas that may be comprised in the precursor flow. The obtaining of the percentage of saturation may thus, be achieved without continuous flow of the precursor flow, thereby allowing for optimized precursor usage. The desired percentage of saturation may be based on the process parameters of the process to be carried out in the process chamber (120) and on the surface topography of the one or more substrates.

In some embodiments, each one of the one or more substrates may have one or more surface enhancement structures. These structures may particularly be present when manufacturing such as for example, 3DDRAM or 3DNAND memory devices.

In embodiments, the provision of the precursor flow to the process chamber (120), while the pump valve (130) is kept closed, may be done for a pre-determined duration. For ALD processing, the pre-determined duration may help obtaining the desired percentage of saturation. The pre-determined duration may be calculated before the provision of the precursor flow to the process chamber (120). The calculation of the pre-determined duration may be executed by a software integrated within the hardware of the semiconductor processing apparatus comprising the process chamber (120), when the desired percentage of surface saturation is inputted.

In embodiments where the provision of the precursor flow comprises providing the first precursor flow and the second precursor flow, the pre-determined duration of the first precursor flow may be the same or different from the pre-determined duration of the second precursor flow.

In embodiments where the provision of the precursor flow comprises providing the first precursor flow, the second precursor flow and the third precursor flow, the pre-determined duration of the first precursor flow, the pre-determined duration of the second precursor flow and the pre-determined duration of the third precursor flow may be the same or different from one another.

In embodiments where the provision of the precursor flow comprises providing the first precursor flow, the second precursor flow, the third precursor flow and the fourth precursor flow, the pre-determined duration of the first precursor flow, the pre-determined duration of the second precursor flow, the pre-determined duration of the third precursor flow and the pre-determined duration of the fourth precursor flow may be the same or different from one another.

In some embodiments, where atomic layer deposition may be taking place, the precursor flow to the process chamber (120) may be stopped after provision of the pre-determined precursor dose. The pre-determined precursor dose may change depending on the surface area to be covered when performing the deposition for the formation of a layer. Thus, the pre-determined dose may depend on the number of substrates to be deposited with the film and the area per substrate. The process parameters, such as for example, the process temperature, the process pressure, flow rate of the precursor flow, the type of the precursor gas comprised in the precursor flow may influence the sticking of the precursor molecules to the substrate surface.

The process may further comprise opening the pump valve (130) after stopping the precursor flow. Opening pump valve (130) may allow the pump (140) to remove the exhaust gas from the process chamber (120). It may be an advantage that the lifetime of the pump that removes the exhaust gas from the process chamber may be prolonged. This may be due to the fact that the duty cycle of the pump may be reduced. The reduction in duty cycle may occur since the pump works intermittently rather than continuously. This may further provide an advantage that maintenance cycles for the pump may be reduced due to the prolonged lifetime.

The controller (160) may further be programmed to repeat the process and to lower the precursor flow during each repetition. In other words, the controller may further be programmed to perform the process one or more times. During each of the one or more times, a precursor flow that may be lower than the precursor flow of the previous time may be provided to the process chamber (120).

In some embodiments, after stopping the precursor flow, the pump valve (130) may still be kept closed before opening it. In other words, there may be a time lag between the stopping of the precursor flow to the process chamber (120) and the opening of the pump valve (130).

Thus, in embodiments, the controller (160) may further be programmed to control the time lag in between the stopping of the precursor flow and the opening of the pump valve. This time lag may advantageously allow for improved surface interaction of the one or more substrates with the precursor that is provided to the process chamber in the precursor flow. The duration of the time lag may be configured based on the precursor type, the number of substrates in the process chamber, the topography on the surface of the substrates, the process temperature and process pressure.

In some embodiments, the carrier gas that may be comprised in the precursor flow may be kept flowing into the process chamber (120) during the time lag.

In some embodiments, the flow of the carrier gas, into the process chamber (120), that may be comprised in the precursor flow may be stopped during the time lag.

In some embodiments, after stopping the precursor flow, the pump valve (130) may be opened without a time lag. In other words, the pump valve (130) may be opened as soon as the precursor flow is stopped.

The controlling provided by the controller (160) in this way may allow for optimizing precursor usage. The optimization of the precursor flow may thus, lead to reducing precursor waste. This may be due to the fact that precursor molecules can have prolonged time to react on a surface site on the one or more substrates. This may particularly be advantageous in comparison to having substrate processing systems where a continuous, uninterrupted flow of precursor is provided to the process chamber, whereby the pump removes the exhaust also continuously through the pump valve that is kept open during the provision of the precursor flow into the process chamber.

Reduction of precursor waste may further lead to a reduction in the cost for processing, particularly for processes where expensive precursor may be used. Reduction in precursor and optimized precursor usage may further be advantageous for improving process sustainability.

The substrate processing system (100) may also allow for a more economical processing of substrates particularly those comprising high surface enhancement structures. This may be due to the fact that substrates having high surface enhancement structures may require an increased amount of precursor usage to be able to coat those structures. Thus, reducing precursor waste may lead to economical processing. Particularly, when a plurality of substrates having high surface enhancement structures are to be processed in a batch apparatus, the required precursor usage may further be increased. Thus, reducing precursor waste, whereby precursor usage is optimized, may become a desired advantage.

In an embodiment, the substrate processing system (100) may further comprise a residual gas analyzer (RGA) (170) as schematically represented in FIG. 2. The residual gas analyzer (170) may be positioned in between the pump valve (130) and the pump (140). The residual gas analyzer (170) may be operably connected to the pump valve (130) and to the pump (140). The residual gas analyzer (170) many be constructed and arranged for determining, in use, a precursor concentration in the exhaust gas.

The residual gas analyzer (170) may provide the advantage of monitoring the precursor concentration in the exhaust gas, when the process chamber is in use. Monitoring may thus, further allow for characterizing the precursor usage. In situations, where an increased concentration of precursor would be detected in the exhaust gas, may thus, allow for taking action for optimizing precursor usage, thereby, reducing precursor waste.

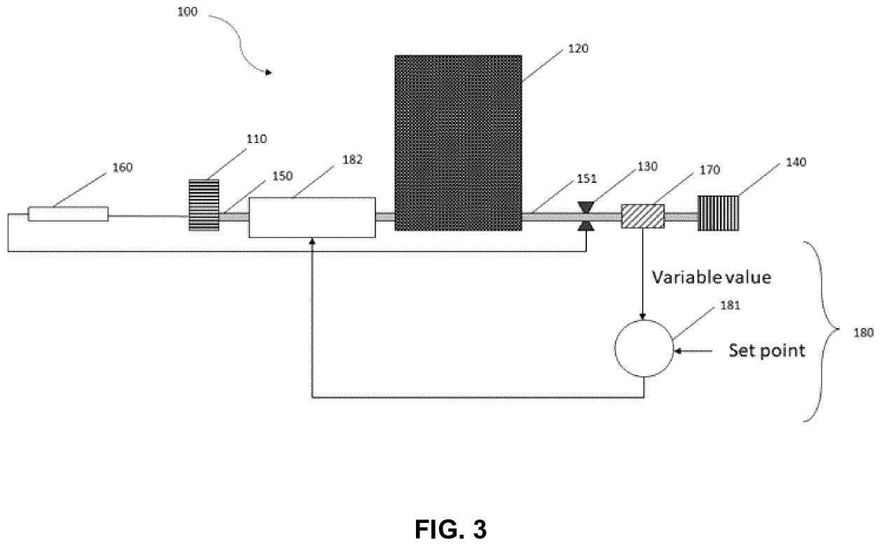

In an embodiment, the residual gas analyzer (170) that may be comprised in a feedback loop control system (180), may be as schematically represented in FIG. 3. The feedback loop control system (80) may be configured for controlling, in use, the precursor concentration in the exhaust gas. The precursor concentration in the exhaust gas may have a variable value. This may depend on the process parameters, the duration of the provision of the precursor flow to the process chamber (120). In case of deposition by ALD, the precursor dose may also play a role in the precursor concentration in the exhaust gas.

The feedback loop control system (80) may further comprise an integrator (181). The integrator (181) may receive an input from the residual gas analyzer (170) regarding the concentration of precursor in the exhaust gas. The input may thus, correspond to the variable value. A desired value for the concentration of precursor in the exhaust gas may be inputted as a set point value to the integrator (181). The integrator (181) may thus, be configured for generating a feedback signal that may correspond to a difference between the desired value of the concentration of the precursor in the exhaust gas and the variable value.

The feedback loop control system (80) may further comprise an effector (182). The effector (182) may be configured for compensating the feedback signal. In other words, it may be stated that the effector (182) may get actuated upon receiving the feedback signal and thus, it may counteract in order to reduce the difference created by the integrator (181), the difference that corresponded to the feedback signal. The effector (182) may create a necessary input into the process chamber (120) to get the desired output. The compensation by the effector (182) may thus, be done by reducing the precursor flow to the process chamber (120), which would be the necessary input. The desire output may thus, be a reduced precursor concentration in the exhaust gas, thereby indicating reduced precursor waste.

In embodiments, where ALD is to be carried out in the process chamber (120), the effector may be configured for compensating the feedback signal by varying the pre-determined precursor dose in the precursor flow to the process chamber (120).

The effector may, in embodiments, thus, be located in between the precursor storage module (160) and the process chamber (120). The variation in the dose of the precursor flow may thus, create another feedback signal by the integrator (181) when the precursor concentration, which is determined by the residual gas analyzer (170), in the exhaust gas is fed back into the feedback loop control system (180).

In embodiments, the controller (160) may further be programmed to operate the feedback loop control system (180) one or more times to repeat the process. Thus, in use, by virtue of determining the precursor concentration in the exhaust gas by the residual gas analyzer (170), the precursor flow may be reduced. As the controller (160) is able to control the flow of the precursor flow to the process chamber (120), while also controlling the closing and the opening of the pump valve (130), it may interact with the feedback loop control system (180) as the effector (182) may be placed in between the precursor storage module (110) and the process chamber (120). Therefore, by interacting with the feedback loop control system (180) one or more times, the controller (160) may further contribute to the optimization of the precursor usage and reducing precursor waste, through the reduction provided in the precursor flow.

In embodiments, where ALD is to be carried out in the process chamber (120), the controller may further be configured to operate the feedback loop control system one or more times so that, in use, by virtue of determining the precursor concentration in the exhaust gas by the residual gas analyzer, the pre-determined precursor dose may be reduced. This may be advantageous since the pre-determined dose may be based on the initial surface area enhancement per wafer. However, as the precursor reacts with this surface, one or more times, the precursor dose may be reduced as the surface area available for deposition by the precursor is likely to be reduced after each one of those one or more times.

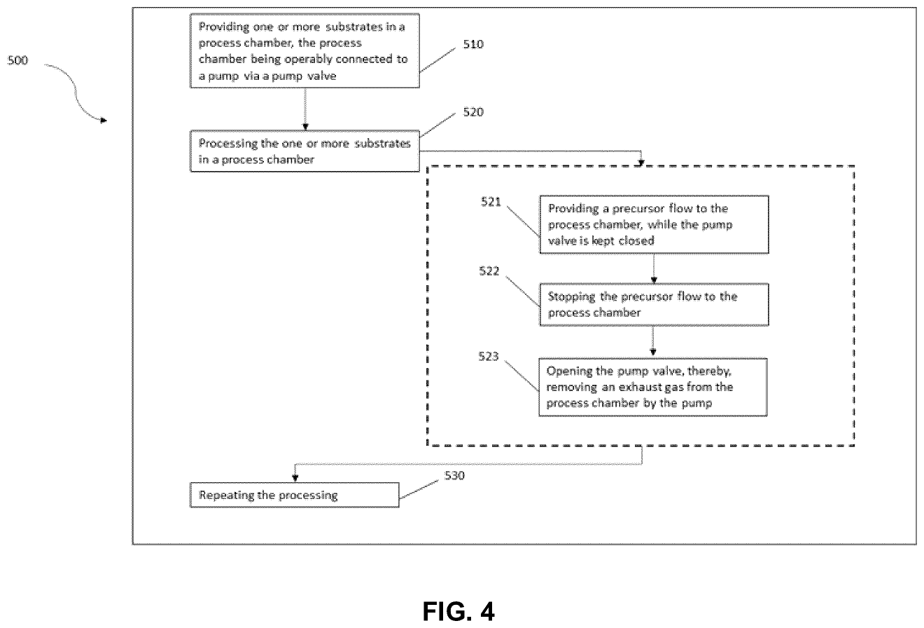

We now return to FIG. 4 representing schematically a method according to embodiments of the second aspect of the present disclosure.

Further described herein is a method (500) of forming a layer on one or more substrates. The method (500) may comprise providing (510), in a process chamber (120), one or more substrates. The one or more substrates may have a surface for forming a layer.

In embodiments, the layer may be a layer of a semiconductor material comprising a Group-IV element, a layer of a semiconductor material comprising a Group III-IV element, a metal, an oxide, a nitride, a carbide, a binary compound, a ternary compound or a quaternary compound.

In some embodiments, the process chamber may be comprised in a single substrate processing apparatus.

In some embodiments, the process chamber may be comprised in a batch apparatus. Batch apparatus may refer to the fact that a plurality of substrates may be processed in the process chamber comprised in such an apparatus.

In some embodiments, the batch apparatus may be an apparatus extending in a longitudinal direction. In some embodiments, the longitudinal direction may be a vertical direction with respect to the ground that the apparatus is positioned. Thus, in some embodiments, the batch apparatus may be a vertical batch apparatus. The vertical batch apparatus may, in embodiments, be a vertical furnace and the process chamber may thus, be comprised in the vertical furnace, whereby the process chamber may also extend in the longitudinal direction being vertical. The process chamber may be constructed and arranged for receiving a plurality of substrates comprised in a substrate boat.

In some embodiments, the longitudinal direction may be a horizontal direction with respect to the ground that the apparatus is positioned. Thus, in some embodiments, the batch apparatus may be a horizontal batch apparatus and the process chamber may thus, extend in the longitudinal direction being horizontal.

The process chamber (120) may be operably connected to a pump (140) via a pump valve (130). The method may further comprise processing (520) the one or more substrates in the process chamber (120).

The processing (520) may comprise providing (521), to the process chamber (120), a precursor flow, while the pump valve (130) may be kept closed. In embodiments where the layer is to be formed by ALD process, the precursor flow may have a pre-determined precursor dose. This may provide the advantage of achieving surface saturation of the one or more substrates with the precursor gas that may be comprised in the precursor flow. Surface saturation may be achieved as the precursor gas may be trapped inside the process chamber (120) without being exhausted while the pump valve (130) is kept closed. This may further provide the advantage of reducing precursor waste, while achieving the surface saturation.

In embodiments, the provision of the precursor flow may be done for a pre-determined duration. This may allow for providing a pre-defined concentration of precursor into the process chamber (120). This may increase the probability of surface interaction of the precursor with the substrate while the pump valve is kept closed, thus reducing precursor waste.

In embodiments where the layer is to be formed by ALD process, the pre-determined duration of the provision of the precursor flow having the pre-determined dose may provide the advantage of obtaining a pre-determined percentage of saturation of the surface of the one or more substrates that may be suitable for forming the layer. The pre-determined percentage may thus be the desired percentage of saturation that may need to be achieved. The pre-determined duration may be calculated before the provision of the precursor flow to the process chamber (120). The calculation of the pre-determined duration may be executed by a software integrated within the hardware of the semiconductor processing apparatus comprising the process chamber (120), when the desired percentage of saturation is inputted.

The processing (520) may further comprise stopping (522) the precursor flow, to the process chamber (120). In embodiments where the layer is to be formed by ALD process, the stopping of the precursor flow, to the process chamber, may be done after provision of the pre-determined dose. Therefore, the stopping of the precursor flow may be done easily after achieving the pre-determined duration. This may provide the advantage of optimized utilization of the precursor in the process chamber (120).

The processing (520) may further comprise opening (523) the pump valve (130) after stopping the precursor flow. This may advantageously allow for removing an exhaust gas from the process chamber (120) by the pump (140). Th exhaust gas may comprise an unreacted portion of the precursor gas comprised in the precursor flow.

In some embodiments, after stopping the precursor flow, the pump valve (130) may still be kept closed before opening it. In other words, there may be a time lag between the stopping of the precursor flow to the process chamber (120) and the opening of the pump valve (130). This time lag may advantageously allow for improved surface interaction of the one or more substrates with the precursor that is provided to the process chamber in the precursor flow. The duration of the time lag may be configured based on the precursor type, the number of substrates in the process chamber, the topography on the surface of the substrates, the process temperature and process pressure.

In some embodiments, the carrier gas that may be comprised in the precursor flow may be kept flowing into the process chamber (120) during the time lag.

In some embodiments, after stopping the precursor flow, the pump valve (130) may be opened without a time lag. In other words, the pump valve (130) may be opened as soon as the precursor flow is stopped.

The method (500) may further comprise repeating (530) the processing, whereby the precursor flow may be lowered during each repetition. Repeating the processing may refer to repeating the processing, comprising the steps (521), (522), (523) as schematized in FIG. 4, one or more times, whereby, during each of the one or more times, the precursor flow may be lower than the precursor flow of the previous time. This may allow for obtaining an incremental reduction in the precursor flow during each of the one or more repetitions. Each incremental reduction may thus, be helpful in achieving optimized precursor usage.

In embodiments, where the formation of the layer is to be performed by ALD process, repeating the processing step may comprise providing, to the process chamber (120), during each of the one or more times, a precursor flow having a precursor dose being lower than the pre-determined dose and being lower than the precursor dose of the previous time. This may be due to the fact that the desired percentage of saturation is likely to be reduced after each one of the one or more times of the repetition, thereby reducing the need for the supply of the precursor dose into the process chamber (120).

In embodiments, the repetition may be done until the precursor concentration in the exhaust gas has reached a minimum value. The repetition may thus, allow for monitoring the change of the precursor concentration in the exhaust gas after each process cycle in an effort to optimize the precursor usage. As the precursor usage is optimized, precursor waste may thus, be reduced.

In embodiments, the method may further comprise determining the precursor concentration in the exhaust gas. This may provide the advantage of monitoring of the precursor concentration in the exhaust gas.

The determination of the precursor concentration in the exhaust gas may be done by a residual gas analyzer (170). The residual gas analyzer (170) may be positioned in between the pump valve (130) and the pump (140). The residual gas analyzer may further be operably connected to the pump valve (130) and to the pump (140). The concentration of precursor that is transported in the exhaust gas in the line (151) between the process chamber (120) and the residual gas analyzer, may thus, be easily measured before the exhaust gas reaches the pump (140) before getting removed from the substrate processing system (100).

In some embodiments, the provision of the precursor flow may comprise providing a first precursor flow and a second precursor flow. The second precursor flow may be different from the first precursor flow. This may provide the advantage of forming a layer of a binary compound on the one or more substrates.

In some embodiments, the first precursor flow and the second precursor flow may be provided alternatingly to the process chamber (120) for forming the binary compound.

In embodiments, the first precursor flow may comprise a first precursor gas and the second precursor flow may comprise a second precursor gas, where the second precursor gas may be different than the first precursor gas.

In embodiments, the provision of the first precursor flow to the process chamber (120), while the pump valve (130) is kept closed, may be done for a first pre-determined duration This may particularly be advantageous when forming the layer by ALD for obtaining the desired percentage of saturation by the first precursor gas.

In embodiments, the provision of the second precursor flow to the process chamber (120), while the pump valve (130) is kept closed, may be done for a second pre-determined duration. This may particularly be advantageous when forming the layer by ALD for obtaining the desired percentage of saturation by the second precursor gas.

In embodiments, the first pre-determined duration may be the same or different from the second pre-determined duration.

In some embodiments, the first precursor flow and the second precursor flow may be provided during an overlapping period to the process chamber (120) for forming the binary compound.

In some embodiments, the first precursor flow and the second precursor flow may be co-flown to the process chamber. In other words, the first precursor flow and the second precursor flow may be provided to the process chamber at the same time during a 100% overlapping period.

In embodiments, the first precursor flow may have a pre-determined first precursor dose and the second precursor flow may have a pre-determined second precursor dose. This may particularly be advantageous when forming the layer by ALD. In use, the pre-determined first precursor dose and the pre-determined second precursor dose may be reduced when the feedback loop control system (180) is operated one or more times.

In some embodiments, the provision of the precursor flow may comprise providing a first precursor flow, a second precursor flow and a third precursor flow. The first, the second and the third precursor flow may be different from one another. This may provide the advantage of forming a layer of a ternary compound on the one or more substrates.

In some embodiments, the first precursor flow, the second precursor flow and the third precursor flow may be provided alternatingly to the process chamber (120) for forming the ternary compound. The first precursor flow may comprise a first precursor gas, the second precursor flow may comprise a second precursor gas, and the third precursor flow may comprise a third precursor gas, where the first, the second and the third precursor gas may be different from one another.

In embodiments, the provision of the first precursor flow to the process chamber (120), while the pump valve (130) is kept closed, may be done for a first pre-determined duration. This may particularly be advantageous when forming the layer by ALD for obtaining the desired percentage of saturation by the first precursor gas.

In embodiments, the provision of the second precursor flow to the process chamber (120), while the pump valve (130) is kept closed, may be done for a second pre-determined duration. This may particularly be advantageous when forming the layer by ALD for obtaining the desired percentage of saturation by the second precursor gas.

In embodiments, the provision of the third precursor flow to the process chamber (120), while the pump valve (130) is kept closed, may be done for a third pre-determined duration. This may particularly be advantageous when forming the layer by ALD for obtaining the desired percentage of saturation by the third precursor gas.

In embodiments, the first pre-determined duration, the second pre-determined duration and the third pre-determined duration may be the same or different from one another. In embodiments, the first precursor flow may have a pre-determined first precursor dose, the second precursor flow may have a pre-determined second precursor dose and the third precursor flow may have a pre-determined third precursor dose. This may particularly be advantageous when forming the layer by ALD. In use, the pre-determined first precursor dose, the pre-determined second precursor dose and the pre-determined third precursor dose may be reduced when the feedback loop control system (180) is operated one or more times.

In some embodiments, the first precursor flow, the second precursor flow and the third precursor flow may be provided during an overlapping period to the process chamber (120) for forming the ternary compound.

In some embodiments, the first precursor flow, the second precursor flow and the third precursor flow may be co-flown to the process chamber. In other words, the first precursor flow, the second precursor flow and the third precursor flow may be provided to the process chamber at the same time during a 100% overlapping period.

In some embodiments, the provision of the precursor flow may comprise providing a first precursor flow, a second precursor flow, a third precursor flow and a fourth precursor flow. The first, the second, the third and the fourth precursor flow may be different from one another. This may provide the advantage of forming a layer of a quaternary compound on the one or more substrates.

In some embodiments, the first precursor flow, the second precursor flow, the third and the fourth precursor flow may be provided alternatingly to the process chamber (120) for forming the quaternary compound. The first precursor flow may comprise a first precursor gas, the second precursor flow may comprise a second precursor gas, the third precursor flow may comprise a third precursor gas, and the fourth precursor flow may comprise a fourth precursor gas where the first, the second, the third and the fourth precursor gas may be different from one another.

In embodiments, the provision of the first precursor flow to the process chamber (120), while the pump valve (130) is kept closed, may be done for a first pre-determined duration. This may particularly be advantageous when forming the layer by ALD for obtaining the desired percentage of saturation by the first precursor gas.

In embodiments, the provision of the second precursor flow to the process chamber (120), while the pump valve (130) is kept closed, may be done for a second pre-determined duration. This may particularly be advantageous when forming the layer by ALD for obtaining the desired percentage of saturation by the second precursor gas.

In embodiments, the provision of the third precursor flow to the process chamber (120), while the pump valve (130) is kept closed, may be done for a third pre-determined duration. This may particularly be advantageous when forming the layer by ALD for obtaining the desired percentage of saturation by the third precursor gas.

In embodiments, the provision of the fourth precursor flow to the process chamber (120), while the pump valve (130) is kept closed, may be done for a fourth pre-determined duration. This may particularly be advantageous when forming the layer by ALD for obtaining the desired percentage of saturation by the fourth precursor gas.

In embodiments, the first pre-determined duration, the second pre-determined duration, the third and the fourth pre-determined duration may be the same or different from one another. In embodiments, the first precursor flow may have a pre-determined first precursor dose, the second precursor flow may have a pre-determined second precursor dose, the third precursor flow may have a pre-determined third precursor dose and the fourth precursor may a fourth pre-determined precursor dose. This may particularly be advantageous when forming the layer by ALD. In use, the pre-determined first precursor dose, the pre-determined second precursor dose, the pre-determined third precursor dose and the pre-determined fourth dose may be reduced when the feedback loop control system (180) is operated one or more times.

In some embodiments, the first precursor flow, the second precursor flow, the third precursor flow, and the fourth precursor flow may be provided during an overlapping period to the process chamber (120) for forming the quaternary compound.

In some embodiments, the first precursor flow, the second precursor flow, the third precursor flow and the fourth precursor flow may be co-flown to the process chamber. In other words, the first precursor flow, the second precursor flow, the third precursor flow and the fourth precursor flow may be provided to the process chamber at the same time during a 100% overlapping period.

Further described herein is a method for forming a layer on one or more substrates. The method may comprise providing one or more substrates in a process chamber. The process chamber may be as described herein. Each one of the one or more substrates may have a surface. The surface may be suitable for forming the layer. The surface may comprise a surface enhancement structure. The surface enhancement structure may have a surface area that may be at least 200 times of a surface area of the substrate. The surface area of the substrate may refer to the area of the surface of a substrate that may be suitable for semiconductor device manufacturing when there is no topography yet present on that surface. The surface area of the substrate surface with no topography may be calculated based on its diameter, such as, for example, being a 200 mm substrate or a 300 mm substrate. The surface area of a 300 mm substrate, for example, may be calculated based on its radius of 15 cm, thus leading to an area of 0.071 m². The surface area introduced by the surface enhancement structure may thus, be at least 200 times of the surface area of the substrate. In embodiments, it may be up to 400 times or up to 600 times depending on the surface enhancement structure. The surface enhancement structures are typically present on the surface of the substrate where semiconductor device manufacturing takes place. This surface is typically referred to as the front side. The side opposite to the front side, which is typically referred to as the back side typically does not have topographical structures.

The method may further comprise processing the one or more substrates, thereby forming the layer on the surface. The processing may comprise providing a precursor flow to the process chamber (120).

In embodiments, the precursor flow may comprise a precursor and where the formation of the layer is to be performed by an ALD process, the precursor may have a pre-determined precursor dose.

A pump valve (130) may be positioned in between the process chamber (120) and a pump (140). The pump (140) may be suitable for removing an exhaust gas from the process chamber (120). The pump valve may be kept closed during the processing.

In embodiments, the method may further comprise repeating the processing, wherein the precursor flow may be lowered during each repetition. Repeating the processing may refer to repeating the processing one or more times, whereby, during each of the one or more times, provision of the precursor flow, to the process chamber (120), may be lower than the precursor flow of the previous time.

In embodiments, where the formation of the layer is to be performed by an ALD process, method may further comprise repeating the processing one or more times, whereby, during each of the one or more times, providing a precursor flow, to the process chamber (120), having a precursor dose being lower than the pre-determined dose and being lower than the precursor dose of the previous time.

The pump valve may thus, be kept closed during the provision of the precursor flow, to the process chamber, the very first time and during each of the one or more times, where the provision of the precursor flow is repeated. Repetition of the precursor flow with reduced precursor flow each time may provide the advantage of optimizing precursor usage. This may then allow for reducing precursor waste. The reduction in the precursor flow each time during the repetition may be thanks to the pump valve being closed, thereby allowing, each time, an increased chance to the precursor comprised in the precursor flow to react with the surface

In embodiments, where the formation of the layer is to be performed by an ALD process, keeping the pump valve closed may provide the advantage of saturating the surface of the one or more substrates. Furthermore, repetition of the precursor flow provision with reduced precursor dose each time may provide the advantage of optimizing precursor usage. This may then allow for reducing precursor waste. The reduction in the precursor dose each time during the repetition may be thanks to the pump valve being closed that may further help in providing reduced surface saturation each time.

In other words, the provision of the precursor flow may be done in a cycle. The cycle may comprise one or more sub-cycles. In each of the subsequent sub-cycles, precursor flow may thus, be lower than the precursor flow of previous sub-cycle. This may thus, allow for obtaining an incremental reduction in the precursor flow with each of the sub-cycles. This may be advantageous in optimizing precursor usage. Optimization in the precursor usage may advantageously lead to reducing precursor waste.

In embodiments, where the formation of the layer is to be performed by an ALD process, in each of the subsequent sub-cycles, the precursor dose in the precursor flow may thus, be lower than the pre-determined precursor dose and may be lower than the precursor dose of previous sub-cycle. This may thus, allow for obtaining an incremental reduction in the precursor dose with each of the sub-cycles. This may be advantageous in optimizing precursor usage. Optimization in the precursor usage may advantageously lead to reducing precursor waste.

In embodiments, each sub-cycle may have a pre-determined duration. The pre-determined duration may be calculated before the provision, to the process chamber (120), of the precursor flow during each sub-cycle. The calculation of the pre-determined duration may be executed by a software integrated within the hardware of a semiconductor processing apparatus comprising the process chamber (120). The duration of a subsequent sub-cycle may, thus be reduced compared to the duration of the sub-cycle prior to that one.

In embodiments, the surface enhancement structure may comprise a gap extending longitudinally in the substrate. The gap may have a bottom surface and be bounded by sidewalls. The sidewalls may comprise a semiconductor material, a dielectric material, a metal or combinations thereof.

In some embodiments, the gap may extend along a first axis. The first axis may be perpendicular to the surface of the substrate, which may be suitable for layer formation and/or may be suitable for semiconductor device manufacturing.

Thus, in some embodiments, the gap may extend longitudinally in the substrate. The gap may have a substantially circular opening, thereby forming a cylindrical hole. The cylindrical hole may, in some embodiments, represent a contact hole in semiconductor device manufacturing. The cylindrical hole may, in some embodiments, represent a via opening in semiconductor device manufacturing. In some embodiments, the cylindrical opening may represent a memory hole made during the manufacturing of a vertical NAND (VNAND) memory device that may also be called as 3D NAND memory device.

In some embodiments, the gap may extend longitudinally in the substrate. The gap may have a substantially rectangular opening, thereby forming a trench.

In some embodiments, the trench may be a slit.

In some embodiments, the gap may extend longitudinally in the substrate along a second axis. The second axis may be perpendicular to the first axis. Thus, the gap may be parallel to the surface of the substrate. The gap may have a substantially rectangular opening, thereby forming a lateral trench. In some embodiments, the lateral trench may represent a Word line entrance made during the manufacturing of a vertical NAND (VNAND) memory device.

Therefore, in some embodiments, the surface enhancement structure may be comprised in an intermediate 3D memory structure.

The substrate processing system and the method of forming a layer on one or more substrates described herein may be suitable for performing deposition processes. They may particularly be suitable for performing an atomic layer deposition (ALD) process or a chemical vapor deposition (CVD) process.

The substrate processing system and the method of forming a layer on one or more substrates described herein may be suitable for depositing such as, for example, a layer of a semiconductor material comprising a Group-IV element, a layer of a semiconductor material comprising a Group III-IV element, a metal, an oxide, a nitride, a carbide, a binary compound, a ternary compound or a quaternary compound.

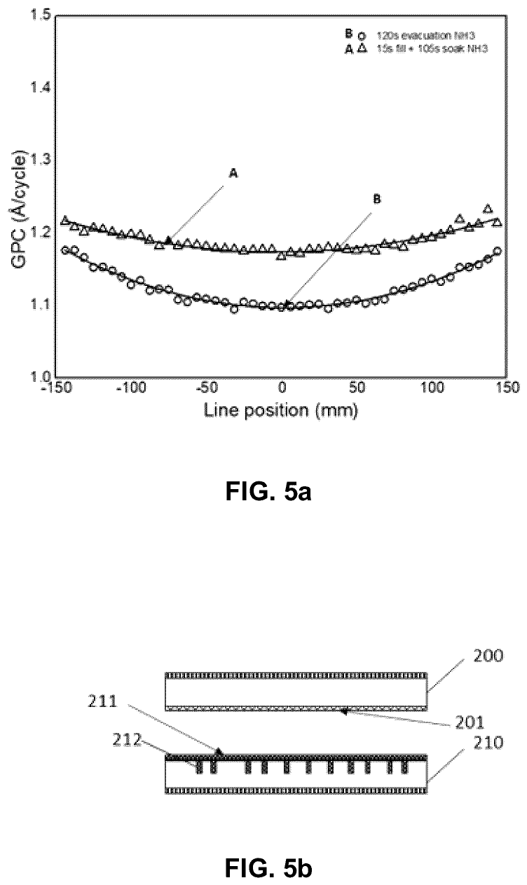

We now return to FIG. 5a showing a graph of a loading test measurement representing the change of growth per cycle (GPC) for growing a layer of a SiN film when providing NH₃ precursor flow as a function of line position. Line position represents the measurements made, in terms of growth per cycle, across the substrate. A batch of substrates having no topography were loaded in a substrate boat. A single device substrate having topography is included in the batch.

In this example, the substrates are subjected to a precursor flow comprising NH₃. NH₃ is provided in the presence of a carrier gas, the carrier gas being N₂. Process temperature is 600° C.

The duration for the provision of the precursor flow is 15 seconds. NH₃ precursor gas has a flowrate of 1 standard liter per minute (slm) and N₂ has a flow rate of 300 standard cubic centimeters per minute (sccm) during the provision. The process pressure is set in a range between 0 to 6 Torr during the provision of the precursor flow.

After stopping the precursor flow, the time lag until the pump valve is opened is 105 seconds. During the time lag N₂ is kept flowing into the process chamber. The pressure during the time lag is in a range between 6 Torr to 10 Torr.

In the loading test measurements, one of the substrates (200) having no topography on its front surface (201), which was placed against a process substrate (210) having topography (212) on its surface (211) in the substrate boat, was measured. The surface (201) of the substrate (200) with no topography faced the surface (211) of the process substrate (210) having the topography (212) is schematically represented in FIG. 5b.

The loading test is performed for two sets of loading test measurements.

In a first set of measurements, NH₃ comprising precursor flow is provided to the process chamber while the pump valve is kept open. The provision of the NH₃ comprising precursor flow is kept for a duration of 120 seconds (graph B in FIG. 5a).

In a second set of measurements, NH₃ comprising precursor flow is provided to the process chamber while the pump valve is kept closed. NH₃ comprising precursor flow is provided for a duration of 15 seconds. After stopping the provision of the flow of NH₃ comprised in the precursor flow, provision of N₂ is further continued while the pump is still kept closed. The time lag in between stopping the flow of NH₃ and opening of the pump valve is set to 105 seconds (graph A in FIG. 5b).

An alternative way of performing a loading test may be to make a Transmission Electron Microscopy (TEM) imaging on the process substrate (210) to monitor thickness of the layer grown on the surface (211).

The graph presented in FIG. 5a provides an indication, as measured on the surface (201) of the substrate (200) without topography, that the GPC of a layer of a silicon nitride film across the surface (211) of the process substrate (210), when the pump valve is kept open (B), shows a variation. This variation is an indication of non-uniformity in thickness. The graph indicates that a higher GPC is obtained close to the edges of the surface of the process substrate (210) compared to its center (Line position=0). A higher GPC indicates a thicker film formation. Thus, variation in thickness of the film formed on the surface (201) of the process substrate (211) is an indication of surface non-uniformity. On the other hand, the GPC across the surface (211) of the process substrate (210), when the pump valve is kept closed (A), shows an improvement since there appears to be a relatively small variation in GPC across the surface extending from the edges to the center. The GPC is improved across the surface of the process substrate, thereby also indicating an improved thickness uniformity. This may be due to the fact that during the time lag, which is 105 seconds (graph A), in other words during the soak time, the precursor has an improved interaction with the surface (211) of the substrate (210) as there is no evacuation of the process chamber since the pump valve is kept closed during the soak time.

This indicates that having a closed pump valve during the provision of the precursor flow into the process chamber and having a time lag in between the stopping of the precursor flow until opening of the pump valve may provide improved thickness uniformity of the deposited layer on the surface of the process substrate.

The embodiments of the present disclosure do not limit the scope of invention as these embodiments are defined by the claims appended herein and their legal equivalents. Any equivalent embodiments are intended to be within the scope of this invention. Modifications of the disclosure that are different from one another, in addition to those disclosed herein, may become apparent to those skilled in the art. Such modifications and the embodiments originating therefrom, are also intended to fall within the scope of the claims appended herein.

1. A substrate processing system for forming a layer on one or more substrates, comprising:
a process chamber constructed and arranged to receive one or more substrates,
a precursor storage module constructed and arranged to provide a precursor flow to the process chamber,
a pump for removing an exhaust gas from the process chamber, the pump being operably connected to the process chamber via a pump valve,
a controller operably connected to the precursor storage module and the pump valve, the controller being configured to execute instructions stored in a non-transitory computer readable medium to control a process for forming the layer comprising:
closing the pump valve prior to providing the precursor flow to the process chamber, providing the precursor flow to the process chamber while the pump valve is kept closed, stopping the precursor flow to the process chamber,
opening the pump valve after stopping the precursor flow,
wherein the controller is programmed to repeat the process and to lower the precursor flow during each repetition.

2. The substrate processing system according to claim 1, wherein the controller is further programmed to control a time lag in between the stopping of the precursor flow and the opening of the pump valve.

3. The substrate processing system according to claim 1, further comprising a residual gas analyzer positioned in between the pump valve and the pump, and the residual gas analyzer being operably connected to the pump valve and to the pump, the residual gas analyzer being constructed and arranged for determining, in use, a precursor concentration in the exhaust gas.

4. The substrate processing system according to claim 3, wherein the residual gas analyzer is comprised in a feedback loop control system, the feedback loop control system configured for controlling, in use, the precursor concentration in the exhaust gas, wherein the precursor concentration in the exhaust gas has a variable value, the feedback loop control system further comprising:
an integrator configured for generating a feedback signal corresponding to a difference between a desired value of the precursor concentration in the exhaust gas and the variable value,
an effector configured for compensating the feedback signal by reducing the precursor flow to the process chamber.

5. The substrate processing system according to claim 4, wherein the controller is further programmed to operate the feedback loop control system one or more times to repeat the process.

6. The substrate processing system according to claim 1, wherein the process chamber is comprised in a vertical furnace.

7. A method of forming a layer on one or more substrates, the method comprising:
providing, in a process chamber, one or more substrates having a surface for forming a layer, the process chamber being operably connected to a pump via a pump valve,
processing the one or more substrates in the process chamber, the processing comprising the steps of:
providing, to the process chamber, a precursor flow, while the pump valve is kept closed, stopping the precursor flow, to the process chamber,
opening the pump valve after stopping the precursor flow, thereby, removing an exhaust gas from the process chamber by the pump,
wherein the method further comprises repeating the processing, whereby the precursor flow is lowered during each repetition.

8. The method according to claim 7, wherein the providing of the precursor flow is done for a pre-determined duration.

9. The method according to claim 7, wherein the repetition is done until a precursor concentration in the exhaust gas has reached a minimum value.

10. The method according to claim 7, wherein the method further comprises determining a precursor concentration in the exhaust gas and wherein the determination is done by a residual gas analyzer, the residual gas analyzer being positioned in between and being operably connected to the pump valve and to the pump.

11. The method according to claim 7, wherein the providing of the precursor flow comprises providing a first precursor flow and a second precursor flow, thereby forming a layer of a binary compound on the one or more substrates, the second precursor flow being different from the first precursor flow.

12. The method according to claim 7, wherein the providing of the precursor flow comprises providing a first precursor flow, a second precursor flow and a third precursor flow, thereby forming a layer of a ternary compound on the one or more substrates, the first, the second and the third precursor flow being different from one another.

13. The method according to claim 7, wherein the process chamber is comprised in a vertical furnace, wherein the process chamber is constructed and arranged for receiving a plurality of substrates comprised in a substrate boat.

14. A method of forming a layer on one or more substrates, the method comprising:
providing, in a process chamber, one or more substrates having a surface, the surface comprising a surface enhancement structure, the surface enhancement structure having a surface area at least 200 times of a surface area of the substrate,
processing the one or more substrates, thereby forming the layer on the surface, wherein the processing comprises providing a precursor flow to the process chamber,
wherein a pump valve, being positioned in between the process chamber and a pump for removing an exhaust gas from the process chamber, is kept closed during the processing.

15. The method according to claim 14, wherein the method further comprises repeating the processing, wherein the precursor flow is lowered during each repetition.

16. The method according to claim 14, wherein the surface enhancement structure comprises a gap extending longitudinally in the substrate.

17. The method according to claim 16, wherein the gap extends longitudinally in the substrate, the gap having a substantially circular opening, thereby forming a cylindrical hole.

18. The method according to claim 16, wherein the gap extends longitudinally in the substrate, the gap having a substantially rectangular opening, thereby forming a trench.

19. The method according to claim 16, wherein the gap extends longitudinally in the substrate and is parallel to the surface, the gap having a substantially rectangular opening, thereby forming a lateral trench.

20. The method according to claim 14, wherein the surface enhancement structure is an intermediate 3D memory device structure.
